(19) United States
(12) Patent Application Publication
(10) Pub. No.: US 2009/0206451 A1
(43) Pub. Date: Aug. 20, 2009

(54) Semiconductor device

(75) Inventors: Hiroyuki Uno, Tokyo (JP); Yasuaki Kobayashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/379,288

(22) Filed: Feb. 18, 2009

(30) Foreign Application Priority Data
Feb. 20, 2008 (JP) 2008-039049

(51) Int. Cl. H01L 25/07

(52) U.S. Cl. 257/618; 257/E25.014

(57) ABSTRACT

A semiconductor device is provided, in which a well contact diffusion layer pattern (13) and a sub-contact diffusion layer pattern (14) are arranged between a P-ch transistor diffusion layer pattern (11) and an N-ch transistor diffusion layer pattern (12), and a CMP dummy pattern (15) is arranged around a P-ch and N-ch transistor arrays. In the device, a data rate exceeding 75% when the well contact diffusion layer pattern and the sub-contact diffusion layer pattern are formed into lines, is reduced to fall within a range of 25% to 75% by forming at least either of the well contact diffusion layer pattern and the sub-contact diffusion layer pattern into dots.

### BACKGROUND OF THE INVENTION

1. Field of the Invention

The present invention relates to semiconductor devices, and in particular, to a semiconductor device having closely arranged patterns whose layout is optimized to cause no adverse effects on yield when planarization is performed by CMP (Chemical Mechanical Polishing).

2. Description of Related Art

Generally, in a semiconductor device that has been subjected to element isolation using STI (Shallow Trench Isolation), the wafer is polished by CMP to planarize the surface. In performing CMP, keeping planarity of the surface is difficult if the density of the patterns to be polished in the processes is not uniform.

In particular, in a portion where the density of patterns is low, the surface portion will be excessively polished to cause recesses (dishing). On the other hand, in a portion where the density of patterns is high, the surface portion may not necessarily be completely planarized. Thus, patterns whose density is low or high will give adverse effects on the yield of manufacturing semiconductor devices. In order to planarize a surface by CMP, the data rate of patterns is said to be required to fall within a range of 25% to 75%, in which case no problem is said to arise. In this way, there has been a demand for a design technique that can permit the data rate to fall within the above range.

For the portion where the density of patterns is low, planarization of the surface portion can be carried out by arranging dummy patterns connected to a floating potential, which has no electrical relationship with the circuit cell, or to a power supply potential, so that the predetermined range of data rate can be met. On the other hand, for the portion where the density of patterns is high, it is necessary to take measures for lowering the data rate by distancing the patterns from each other or dividing the patterns, because the elements required for the circuit cell cannot be eliminated. This measure, however, may lead to the increase in the size of a chip, and is difficult to be used as a measure for planarization.

Meanwhile, Japanese Patent Laid-Open No. 6-29500 discloses a master slice type semiconductor integrated circuit having a P-ch transistor array and an N-ch transistor array, which are arranged facing each other. This circuit is configured to include, between the P-ch transistor array and the N-ch transistor array, an N-type diffusion region (well contact diffusion layer) formed on an N-well, and to include a P-type diffusion region (sub-contact diffusion layer) formed between the well contact diffusion layer and the N-ch transistor array. Japanese Patent Laid-Open No. 2006-253393 also discloses a similar structure. In this way, a well contact diffusion layer and a sub-contact diffusion layer have been arranged between P-ch and N-ch regions to form lines. Such an arrangement has been used to take a measure for latch-up in P-ch and N-ch transistors.

In making a layout design, a number of circuit cells of basic logic are prepared to design a block by combining the cells. In this case, for the enhancement of the efficiency of designing, it is assumed that the cells are formed to have a uniform height and to have a width which is a multiple of a certain pitch, so that a plurality of cells can be arranged in vertical and horizontal directions to form a block.

For example, as shown in FIG. 2, in a semiconductor device using a circuit cell of transistors, the circuit cell includes: a plurality of transistor diffusion layer patterns (P-ch transistor diffusion layer pattern 21 and N-ch transistor diffusion layer pattern 22); a well contact diffusion layer (well contact diffusion layer pattern 23) for suppressing power supply potential variation and latch-up and a sub-contact diffusion layer (sub-contact diffusion layer pattern 24); and CMP dummy diffusion patterns (CMP dummy patterns 25) formed into dots, for suppressing variation in CMP.

Accordingly, as elements are miniaturized, the density will become higher in the patterns of the well contact diffusion layer and the sub-contact diffusion layer. Thus, when CMP is performed, an interlayer insulating film may be less sufficiently polished than the surrounding, inducing variation in the thickness of the base surface.

Among the elements, transistors are indispensable for actual circuit operation, and the well contact diffusion layer and the sub-contact diffusion layer are indispensable for suppressing power supply potential variation and latch-up.

In this way, the actual situation has been that the enhancement of integration is limited in a semiconductor integrated circuit where such a well contact diffusion layer and a sub-contact diffusion layer are arranged.

Thus, in a semiconductor integrated circuit in which a P-ch transistor array and an N-ch transistor array are arranged facing each other, a semiconductor device arranged with a well contact diffusion layer and a sub-contact diffusion layer between both transistor arrays, has been demanded to have a layout optimized into patterns that will give no adverse effects on yield at the time of performing planarization by CMP, even with the integration of the device is enhanced.

### SUMMARY

The present inventors have found that a data rate can be reduced to fall within a range optimal for CMP, by dividing a well contact diffusion layer and a sub-contact diffusion layer into dots which layers have conventionally been arranged, being formed into lines. Also, the inventors have found that formation of a well contact diffusion layer and a sub-contact diffusion layer into dots can also fulfill the conventional function of suppressing power supply potential variation and latch-up by supplying power supply potential to each of the dots.

According to one embodiment, a semiconductor device is provided, the device comprising: a P-ch transistor array and a N-ch transistor array, which are arranged facing each other; a well contact diffusion layer and a sub-contact diffusion layer, which are arranged between both transistor arrays; and a CMP dummy pattern arranged around the P-ch and N-ch transistor arrays, wherein at least either of the well contact diffusion layer and the sub-contact diffusion layer is formed into dots.

Thus, the data rate in a field can be approximated to a range (of 25% to 75%) that will cause no problem in CMP, by forming the well contact diffusion layer and the sub-contact diffusion layer into dots, which layers can suppress power supply potential variation and latch-up. As a result, a circuit cell can be provided, which can keep the base surface to be planar. This will lead to the enhancement of yield in manufacturing semiconductors.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a view illustrating circuit cell patterns having patterns of a well contact diffusion layer and a sub-contact diffusion layer, according to an exemplary embodiment;

FIG. 2 is a view illustrating circuit cell patterns having shapes of a well contact diffusion layer and a sub-contact diffusion layer, according to a conventional example;

FIG. 3 is a view illustrating a high-density portion of patterns in a circuit cell having shapes of a well contact diffusion layer and a sub-contact diffusion layer, according to a conventional example;

FIG. 4 is a view illustrating a high-density portion of patterns in a circuit cell having shapes of a well contact diffusion layer and a sub-contact diffusion layer, with an improved data rate;

FIG. 5 is a view exemplifying a pattern density of a conventional example for explaining the advantages of the present invention;

FIG. 6 is a view exemplifying a pattern density according to an exemplary embodiment for explaining the advantages of the present invention;

FIG. 7 is a block diagram illustrating a semiconductor integrated circuit using the circuit cell patterns of FIG. 6;

FIG. 8 is a view illustrating patterns of a conventional example for explaining another exemplary embodiment; and

FIG. 9 is a view illustrating circuit cell patterns having patterns of well contact diffusion layer and a sub-contact diffusion layer, according to another exemplary embodiment.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

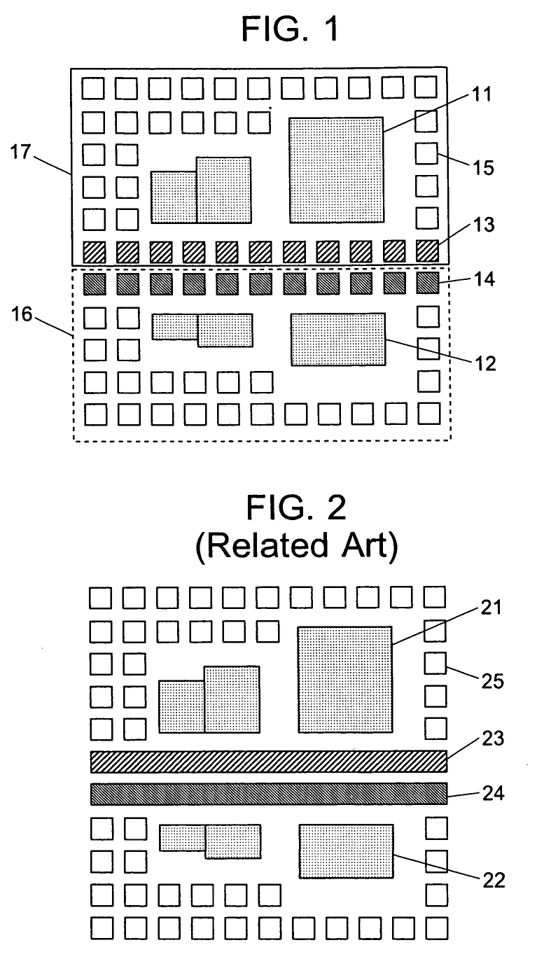

FIG. 1 is a view illustrating patterns of an integrated circuit device, according to an exemplary embodiment. Well contact diffusion layer pattern 23 and sub-contact diffusion layer pattern 24 shown in FIG. 2 have been changed, in FIG. 1, into well contact diffusion layer pattern 13 and sub-contact diffusion layer pattern 14 formed of dots. P-ch transistor diffusion layer pattern 11, N-ch transistor diffusion layer pattern 12 and CMP dummy pattern 15 remain the same as patterns 21, 22 and 25, respectively, of FIG. 2.

In FIG. 1, a semiconductor device is formed in a P-type semiconductor substrate. P-ch transistor diffusion layer pattern 11 is formed in N-type well 17, and N-ch transistor diffusion layer pattern 12 is formed in P-type well 16.

N-ch transistor diffusion layer pattern 12 can be formed directly in the P-type semiconductor substrate, when the P-type well is not formed in the semiconductor substrate.

In this embodiment, well contact diffusion layer means a diffusion layer electrically connected to the N-type well, and sub-contact diffusion layer means a diffusion layer electrically connected to the P-type well or P-type substrate.

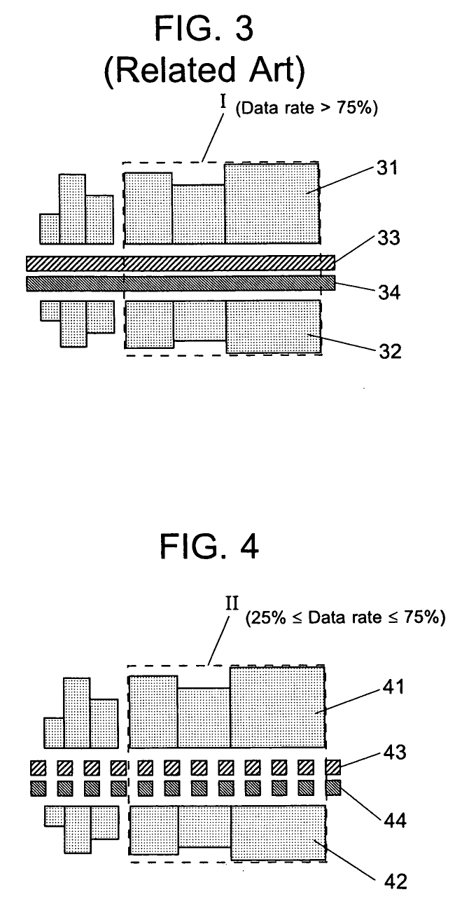

With reference to FIGS. 3 and 4, the exemplary embodiment will be described further. FIG. 3 shows a circuit cell having high-density diffusion layers that will cause a problem when CMP is performed. FIG. 4 is a view illustrating an example to which the present invention has been applied, for avoiding the problem.

In order to reduce the size of a circuit cell, the same node diffusion layers are shared very often. It is difficult to completely planarize a base face by CMP in a portion having a buffer or the like with large-size transistors, which portion (I) corresponds to a portion where the density of diffusion layers is high in FIG. 3. In this case, a measure that is required to be taken is to space apart the transistor diffusion layer patterns (P-ch transistor diffusion layer pattern 31 and N-ch transistor diffusion layer pattern 32) from well contact diffusion layer pattern 33 and sub-contact diffusion layer pattern 34, or to divide the transistor diffusion layers that are shared.

In this regard, well contact diffusion layer pattern 43 and sub-contact diffusion layer pattern 44 located at a P-N boundary portion may be formed into dots as shown in FIG. 4. With this formation, the data rate of the portion (II) may be permitted to fall within a range (of 25% to 75%) that will cause no problem in CMP, without having to take the above measure. Further, the well contact and sub-contact diffusion layers formed into dots can achieve the conventional purpose of suppressing power supply potential variation and latch-up, by supplying power supply potential to each of the dots.

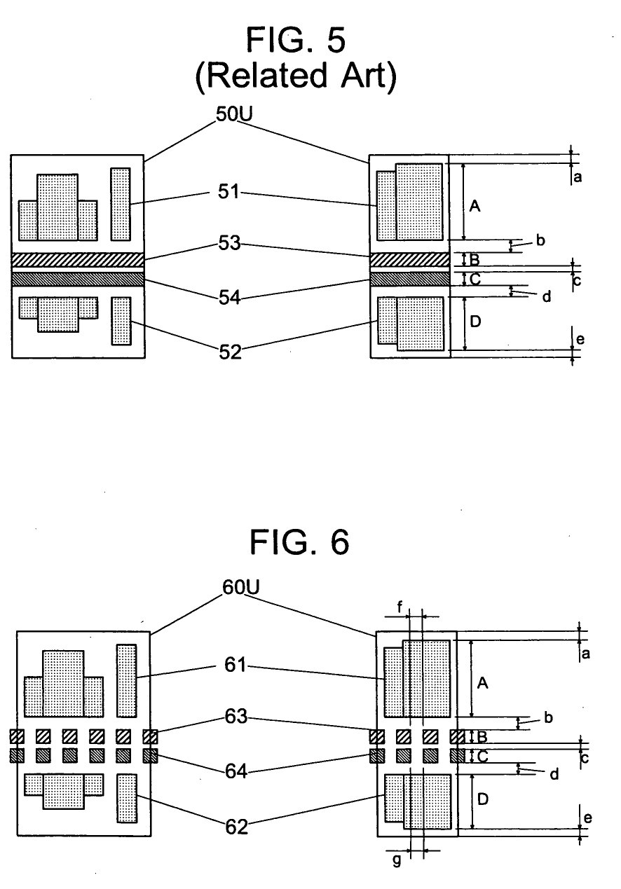

Referring now to FIGS. 5 and 6, the advantages of the present invention are specifically described. When the present invention is applied to a circuit cell shown in FIG. 5, the circuit cell will have a form as shown in FIG. 6. In FIG. 6, the centers of well contact diffusion layer pattern 63 and sub-contact diffusion layer pattern 64 are positioned on the pitch of the cell width. Thus, cells can be vertically and horizontally arranged with a basic unit 60 of the circuit cell in the figure to construct a block.

In FIGS. 5 and 6, indicated by (A) is a size of a P-ch transistor, by (B) is a width of a well contact diffusion layer, by (C) is a width of a sub-contact diffusion layer, by (D) is a size of an N-ch transistor, by (a) is an interval between the P-ch transistor and a cell boundary, by (b) is an interval between the P-ch transistor and the well contact diffusion layer, by (c) is an interval between the well contact diffusion layer and the sub-contact diffusion layer, by (d) is an interval between the N-ch transistor and the sub-contact diffusion layer, by (e) is an interval between the N-ch transistor and a cell boundary, by (f) is an interval between dots of the well contact diffusion layer and by (g) is an interval between dots of the sub-contact diffusion layer. As mentioned above, since the cells are horizontally arranged in making a block, the values of (B), (C) and (c) are fixed. Accordingly, the diffusion layers will have the highest density, in this circuit cell, when (A) and (D) are maximum and when (a), (b), (d) and (e) are minimum.

Let us take an example of a circuit cell where the maximum of (A) is 6 μm, (B) is 1 μm, (C) is 1 μm, the maximum of (D) is 4 μm, the minimum of (a) is 0.5 μm, the minimum of (b) is 1 μm, (c) is 0.5 μm, the minimum of (d) is 1 μm, the minimum of (e) is 0.5 μm, the height of the cell is 15.5 μm, and, in FIG. 6, each of (f) and (g) is 1 μm. In FIG. 5, the data rate when the diffusion layers have the highest density is 12/15.5=77.4%, which will cause variation in the height when CMP is performed. On the other hand, in the case shown in FIG. 6, the data rate when the diffusion layers have the highest density is 11/15.5=71.0%. This data rate corresponds to the data rate that will cause no adverse effects in performing CMP.

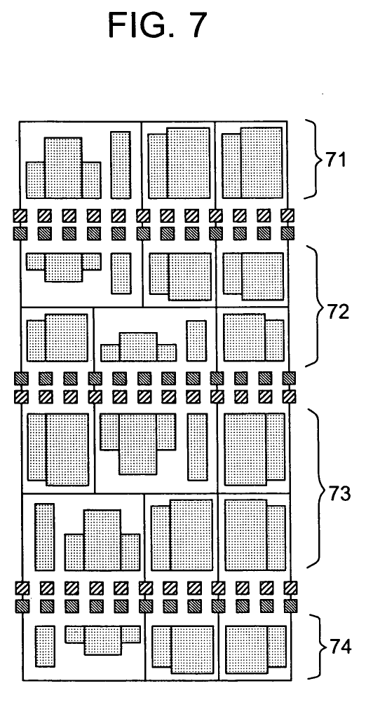

Using the circuit cell patterns of FIG. 6, a block design shown in FIG. 7 can be formed. Thus designed blocks can be planarized by CMP throughout the entire integrated circuit device.

### (Other Exemplary Embodiments)

In the exemplary embodiment described above, the well contact diffusion layer pattern and the sub-contact diffusion layer pattern have been formed into square dots, similar to the dots of the CMP dummy pattern, and to have substantially the same size. However, the shape and size of the well contact and sub-contact diffusion layer patterns as well as the CMP dummy pattern can be optionally changed.

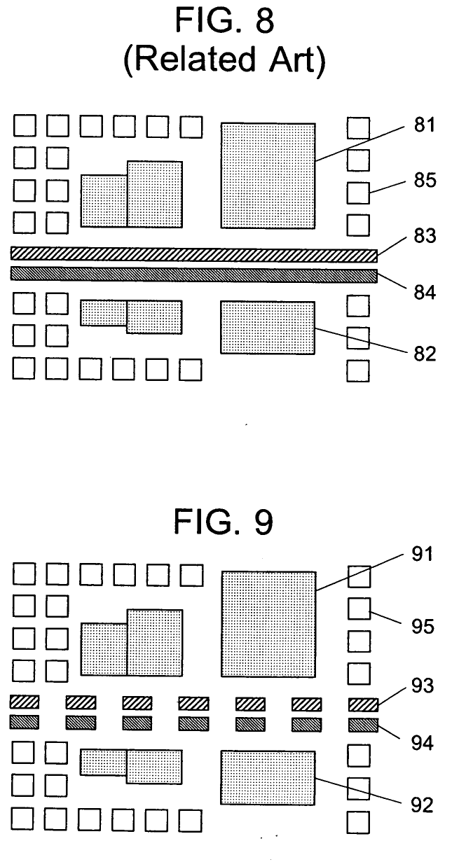

The CMP dummies are mostly formed to have a size a little larger than a minimum standard in a layout in order to prevent pattern inclination or skipping. As shown in FIG. 8, in the case of a circuit cell where the widths of well contact diffusion layer pattern 83 and sub-contact diffusion layer pattern 84 are smaller than the size of the CMP dummy pattern, forming each of the diffusion layers into a pattern of square dots as in the above exemplary embodiment, will increase the number of dots, necessitating supply of power supply potential to each of the dots. Contrarily, when the widths of the diffusion layer patterns are increased to obtain dots of the same size as those of the CMP dummy pattern, the vertical cell size will be increased.

Measures can be taken for this. Specifically, as shown in FIG. 9, the sides (widths) of well contact and sub-contact diffusion layer patterns 93 and 94, which sides (widths) are influenced by the cell size, may be the same as those of patterns 83 and 84 shown in FIG. 8. However, each of the dots may be lengthened to the sides which are not influenced by the cell size. As a result, the number of dots can be prevented from increasing, the cell size will not be increased, and the base surface can be planarized.

The above description has been provided taking examples in which both of the well contact and sub-contact diffusion layer patterns have been formed into dots. Alternative to this, either one of the diffusion layer patterns may be formed into dots, if the data rate can fall within the range (of 25% to 75%) that causes no problem in CMP.

A semiconductor device can be formed in an N-type semiconductor substrate. In this case, the N-ch transistor array pattern is formed in the P-type well, and the P-ch transistor array pattern is formed in the N-type well or directly in the N-type semiconductor substrate. And in this case, the well contact diffusion layer means a diffusion layer electrically connected to the P-type well, and the sub-contact diffusion layer means a diffusion layer electrically connected to the N-type well or N-type semiconductor substrate.

What is claimed is:

1. A semiconductor device comprising:
a P-ch transistor array and an N-ch transistor array, which are arranged facing each other;
a well contact diffusion layer and a sub-contact diffusion layer, which are arranged between both transistor arrays; and
a CMP dummy pattern arranged around the transistor arrays, wherein at least either of the well contact diffusion layer and the sub-contact diffusion layer is formed into dots.

2. The semiconductor device according to claim 1,
wherein a data rate exceeding 75% when the well contact diffusion layer and the sub-contact diffusion layer are formed into lines is reduced to 25% to 75% by forming the diffusion layers into dots.

3. The semiconductor device according to claim 1,
wherein both of the well contact diffusion layer and the sub-contact diffusion layer are formed into dots.

4. The semiconductor device according to claim 1,
wherein each of the dots is formed to have the same size as the dummy pattern.

5. The semiconductor device according to claim 1,
wherein each of the dots has a rectangular shape being lengthened to sides which give no influence on a cell size.

6. A semiconductor device comprising:
a P-type semiconductor substrate;
an N-type well disposed in the semiconductor substrate;
a P-type well disposed in the semiconductor substrate;
a P-ch transistor array disposed in the N-type well;
an N-ch transistor array disposed in the p-type well, the P-ch transistor array and the N-ch transistor array being located facing each other;
a plurality of CMP dummy diffusion layers, which are arranged around the N-type transistor array and the P-type transistor array;
a plurality of sub-contact diffusion layers disposed in the P-type well, being located between the N-type transistor array and the P-type transistor array; and
a plurality of well contact diffusion layers disposed in the N-type well, being located between the N-type transistor array and the P-type transistor array,
wherein at least one of the well contact diffusion layer and the sub-contact diffusion layer is formed into a square shape.

7. The semiconductor device according to claim 6,
wherein the CMP dummy diffusion layer is formed into a square shape.

8. The semiconductor device according to claim 7,
wherein at least one of the well contact diffusion layer and the sub-contact diffusion layer is formed to have the same size as the CMP dummy diffusion layer.

9. The semiconductor device according to claim 6,
wherein a data rate of pattern area for patterning diffusion layers which include all diffusion layers ranges from 25% to 75%.
